(19) United States
(12) Patent Application Publication
(10) Pub. No.: US 2025/0341680 A1
(43) Pub. Date: Nov. 6, 2025

(54) PACKAGING FOR COMPACT OBJECT-SCANNING MODULES

(71) Applicant: Google LLC, Mountain View, CA (US)

(72) Inventors: Frank BAI, Waterloo (CA); John DOMM, Kitchener (CA); Kourosh KHOSRAVIANI, North York (CA); Talha KOSE, Kitchener (CA); Geoffrey Wesley LEE, Kitchener (CA); Zhenhao LI, Waterloo (CA); Kenneth MCCOUBREY, Kitchener (CA); Arash ROHANI, Waterloo (CA); Niladri SARKAR, Waterloo (CA); Duncan Wesley STRATHEARN, Waterloo (CA); Dong YAN, Richmond Hill (CA); Nino ZAHIROVIC, Waterloo (CA)

(21) Appl. No.: 19/268,326

(22) Filed: Jul. 14, 2025

Related U.S. Application Data
(63) Continuation-in-part of application No. 17/681,503, filed on Feb. 25, 2022, now Pat. No. 12,360,361.
Application No. 17/681,503 is a continuation-in-part of application No. 16/232,410, filed on Dec. 26, 2018, now Pat. No. 11,262,577.
(60) Provisional application No. 62/610,493, filed on Dec. 26, 2017.

(51) Int. Cl. G02B 6/35; G02B 6/42; H01S 5/02253

(52) U.S. Cl. CPC G02B 6/3584; G02B 6/4262; H01S 5/02253

(57) ABSTRACT

The present disclosure is directed to compact packaging for optical MEMS devices, such as one- and two-dimensional beam scanners. An embodiment in accordance with the present disclosure includes a housing that defines a sealed chamber that encloses a light source, a MEMS scanner having a scanning element for steering at least a portion of a light signal provided by the light source in two dimensions as an output signal, an optical element for collimating and/or redirecting the light signal, and a monitor photodiode for providing a local feedback signal based on the orientation of the scanning element. Preferably, the MEMS scanner and the monitor photodiode are monolithically integrated on the same substrate and the housing is configured as an electrostatic shield for the components located in the sealed chamber.

### CROSS REFERENCE TO RELATED APPLICATIONS

This application is a continuation-in-part of co-pending U.S. Non-Provisional patent application Ser. No. 17/681,503, filed Feb. 25, 2022 (Attorney Docket: 3146-002US2), which is a continuation-in-part of co-pending U.S. Non-Provisional patent application Ser. No. 16/232,410 (now U.S. Pat. No. 11,262,577), filed Dec. 26, 2018 (Attorney Docket: 3146-002US1), which claims the benefit of U.S. Provisional Patent Application Ser. No. 62/610,493 filed Dec. 26, 2017 (Attorney Docket: 3146-002PR1), each of which is incorporated by reference as if set forth at length herein.

This application also includes concepts disclosed in U.S. Patent Publication No. US2016/0166146, published Jun. 16, 2017 (Attorney Docket: 3001-004US1), and U.S. Patent Publication No. US2017/0276934, published Sep. 28, 2017 (Attorney Docket: 3001-004US2), each which is incorporated by reference as if set forth at length herein. If there are any contradictions or inconsistencies in language between this application and the cases that have been incorporated by reference that might affect the interpretation of the claims in this case, the claims in this case should be interpreted to be consistent with the language in this case.

### TECHNICAL FIELD

The present disclosure relates to optical packaging in general and, more particularly, to packaging for optical systems and sub-systems, such as beam-scanner modules.

### BACKGROUND

Beam scanners that integrate infrared (IR) illumination, beamforming and two-dimensional scanning functions are useful in a number of applications, such as eye tracking, micro-gesture recognition, industrial light curtains, range finding using LIDAR or point-cloud projection, free-space optical communication, path planning and control in robotics, object tracking in VR, to name a few.

Prior-art beam scanners are typically based on scanning mirrors and actuators for moving them that are all on the order of one millimeter (mm). To enable a large rotation, the package that surrounds the scanning mirror must have sufficient clearance. As a result, the dimensions of a prior-art packaged scanning mirror are necessarily quite large. In addition, in prior-art light-scanning systems, the light sources and refractive collimating optics required to produce a collimated light beam reside outside the scanning-mirror package, further increasing the space required for such beam scanners. Still further, these light sources and optical elements are typically large, bulky, and expensive, which can limit their utility in some applications.

A compact beam scanner that enables object tracking with high resolution and low cost would be a significant advance in the state of the art.

### SUMMARY

The teachings of the present disclosure enable the reduction of the footprint and profile of a packaged beam scanner suitable for use in an object-tracking system. Embodiments in accordance with the present disclosure are particularly well suited for use in systems for eye tracking, micro-gesture recognition, industrial light curtains, range finding using LIDAR or point-cloud projection, free-space optical communication, path planning and control in robotics, object tracking in virtual-reality and/or augmented reality systems. Furthermore, the packaging concepts described herein are suitable for use in mobile products, such as smart watches, smart phones, smart glasses, and the like, many of which require components and modules having an extremely small footprint.

An illustrative embodiment is a beam scanner comprising a light source, collimating optics, a MEMS scanner, and a plurality of monitor photodetectors for providing local feedback for the position of the scanning element, which are enclosed within a sealed chamber of a low-profile package housing. The light source is a vertical-cavity surface-emitting laser (VCSEL), which provides a light signal to a scanning element of the MEMS scanner via the collimating optics. The scanning element is a mirror whose orientation about two axes is controlled via a pair of actuators. The mirror reflects the collimated beam as an output beam that exits the module, while the mirror position is monitored by the monitor photodetectors, which are monolithically integrated with the MEMS scanner on the same substrate. In some embodiments, the scanning element at least partially collimates the light signal. Furthermore, the housing is configured to function as an electrostatic shield for the MEMS scanner, light source, and monitor photodiodes. The housing is also configured to mitigate propagation of scattered light within the package.

In some embodiments, the substrate includes a cavity that enables the light source to be positioned directly beneath the scanning element, which includes an aperture to enable the light signal to pass through the scanning element.

In some embodiments, the MEMS scanner includes at least one region that mitigates transmission of scattered light from the MEMS scanner.

In some embodiments, the housing includes a cover having an anti-reflection coating on at least one of its inner and outer surfaces. In such embodiments, Fresnel reflections of the output beam generated at the other one of the inner and outer surfaces or a surface external to the module are received by the photodiode to enable it to monitor the position of the scanning element. In some embodiments, each of the inner and outer surfaces of the cover include an AR coating such that the output beam can pass through both surfaces and reflect off a stationary surface external to the scanner.

An embodiment in accordance with the present disclosure is a beam scanner comprising: a light source configured to provide a light signal; an optical element configured to receive the light signal and provide a first portion of the light signal as a collimated beam; a MEMS scanner that is operative for steering the first portion in two dimensions, the MEMS scanner including a scanning element, a first actuator for rotating the scanning element about a first axis, and a second actuator for rotating the scanning element about a second axis; a first photodetector that is configured to provide a feedback signal based on a second portion of the light signal, wherein the second portion is based on an orientation of the scanning element about at least one of the first axis and second axis; and a housing that includes a first substrate, a body, and a cover that comprises a first material that is substantially transparent for the light signal, wherein the first substrate, body, and cover collectively define a chamber that is sealed to maintain a first environment, and wherein the chamber contains the light source, the MEMS scanner, and the first photodetector; wherein the MEMS scanner directs the first portion through the cover as an output signal.

Another embodiment in accordance with the present disclosure is method including: providing a housing that includes a first substrate, a body, and a cover that comprises a first material that is substantially transparent for a light signal, wherein the first substrate, body, and cover collectively define a chamber that is sealed to maintain a first environment, and wherein the chamber contains a light source, an optical element, a MEMS scanner, and a first photodetector; enabling the light source to provide the light signal; collimating the light signal at the optical element as a collimated beam and directing the collimated beam to a MEMS scanner comprising a scanning element for steering the collimated beam in two dimensions, wherein the MEMS scanner includes the scanning element, a first actuator for rotating the scanning element about a first axis, and a second actuator for rotating the scanning element about a second axis; providing a feedback signal based on a first portion of the light signal, wherein the feedback signal is provided by the first photodetector, and wherein the first portion is based on an orientation of the scanning element about at least one of the first axis and second axis; and directing a second portion of the collimated beam through the cover as an output signal via the MEMS scanner.

### BRIEF DESCRIPTION OF THE DRAWINGS

FIG. 1 depicts a schematic drawing of a cross-sectional view of an illustrative embodiment of a beam scanner suitable for use in an object-tracking system in accordance with the present disclosure.

FIG. 2 depicts a schematic drawing of a perspective view of MEMS substrate 112.

FIGS. 3A-E depict body 118 at different stages of an exemplary fabrication process suitable in accordance with the present disclosure.

FIG. 4 depicts a schematic drawing of an alternative mitigation region in accordance with the present disclosure.

FIG. 5 depicts a schematic drawing of a cross-sectional view of an alternative embodiment of a beam scanner suitable for use in an object-tracking system in accordance with the present disclosure.

FIG. 6 depicts a schematic drawing of a cross-sectional view of another alternative embodiment of beam scanner suitable for use in an object-tracking system in accordance with the present disclosure.

### DETAILED DESCRIPTION

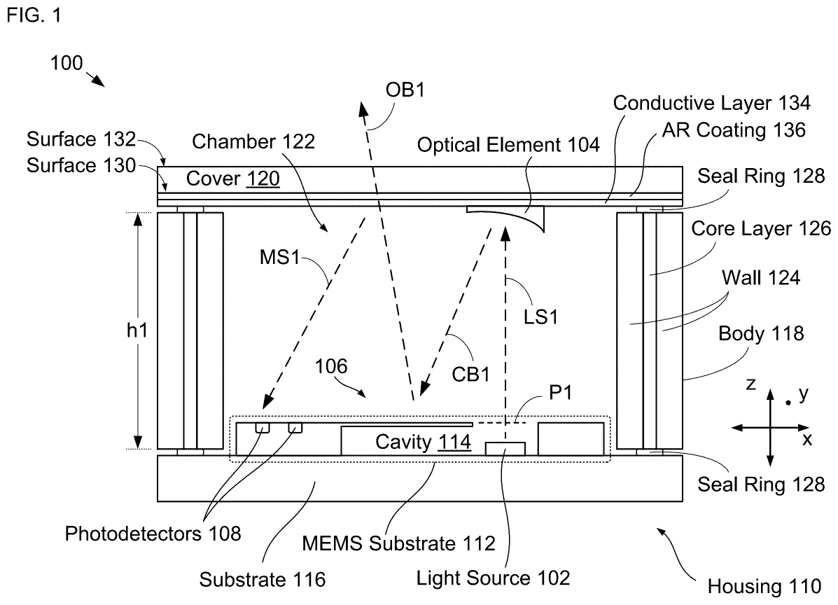

FIG. 1 depicts a schematic drawing of a cross-sectional view of an illustrative embodiment of a beam scanner suitable for use in an object-tracking system in accordance with the present disclosure. Beam scanner 100 is a compact beam-scanner module operative for steering a substantially collimated beam in two dimensions, where the collimated beam is directed through a portion of housing 110 for subsequent detection by one or more external photodetectors located outside of the beam-scanner module. Beam scanner 100 includes light source 102, optical element 104, MEMS scanner 106, and monitor photodetectors 108, all of which are enclosed within housing 110.

Light source 102 is a conventional vertical-cavity surface-emitting laser (VCSEL) suitable for use in embodiments in accordance with the present disclosure. In some embodiments, a different light source, such as a super-luminescent diode, is included in beam scanner 100. One skilled in the art will recognize, after reading this Specification, that the choice of light source 102 normally depends on the external photodetector(s) used with beam scanner 100. Typically, beam scanner 100 is intended for operation with an external photodetector comprising a silicon photodetector, which is sensitive for wavelengths up to 1020 nm; however, other external photodetector and/or wavelengths can be used without departing from the scope of the present disclosure.

In the depicted example, light source 102 provides light signal LS1 to optical element 104, which collimates the light signal and redirects it as collimated beam CB1 toward a scanning element included in MEMS scanner 106.

Optical element 104 is an off-axis parabolic mirror; however, in some embodiments, optical element 104 is a different optical element. One skilled in the art will recognize, after reading this Specification, that myriad optical elements can be used for optical element 104 without departing from the scope of this disclosure. Examples of optical elements suitable for use in embodiments in accordance with the present application include, without limitation, reflective lenses, diffractive elements, holographic elements, metalenses, metasurfaces, and the like.

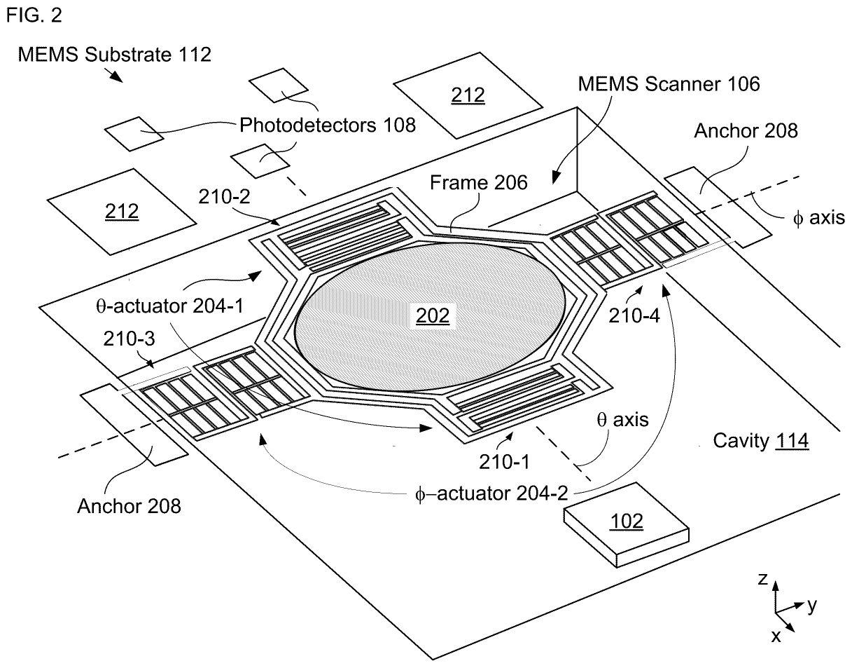

MEMS scanner 106 is a two-dimensional (2D) scanning system that includes a scanning element and a pair of actuators that are collectively operative for steering collimated beam CB1 in two dimensions such that it exits housing 110 as output beam OB1. MEMS scanner 106 is described in more detail below and with reference to FIG. 2, as well as in parent applications U.S. Ser. Nos. 17/681,503 and 16/232,410.

Each of monitor photodetectors 108 is a photodiode formed in the top surface of MEMS substrate 112. As a result, MEMS scanner 106 and monitor photodetectors 108 are monolithically integrated on the same substrate (i.e., MEMS substrate 112). In some embodiments, one or more monitor photodetectors are disposed on a different substrate than that containing the MEMS scanner.

In some embodiments, at least one of monitor photodetectors 108 comprises a photosensitive device other than a photodiode, such as an avalanche photodiode (APD), phototransistor, photoconductor, a metal-semiconductor-metal (MSM) photodetector, and the like.

FIG. 2 depicts a schematic drawing of a perspective view of MEMS substrate 112. MEMS scanner 106 and monitor photodetectors 108 are monolithically integrated on substrate 112 such that they are electrically isolated from one another, while light source 102 is disposed on the MEMS substrate using conventional bonding technology. For clarity, wire bonds, conductive traces, and vias for enabling electrical communication to these devices are not shown in FIG. 2; however, it will be clear to one skilled in the art, after reading this Specification, how to provide electrical communication to devices disposed on MEMS substrate 112. In some embodiments, light source 102 is placed on the substrate 116 such that the light source sits beside the MEMS. In some embodiments, the substrate has an additional cavity, in which the MEMS device sits at a lower level than the light source beside it.

As noted above, the depicted example includes three monitor photodetectors that are monolithically integrated with a MEMS scanner on the same substrate. Monitor photodetectors 108 are arranged in a pattern (e.g., a triangle, etc.) that enables highly accurate monitoring of the orientation of scanning element 202 about the θ- and φ-axes. In addition, in some embodiments, one or more monitor photodetectors 108 are shaped such that they appear as circles in the scan space of MEMS scanner 106. In some embodiments, a plurality of monitor photodetectors 108 are employed, where each monitor photodetector has a significantly different shape such that it is readily identified within the scan space of MEMS scanner 106. In the resultant signal, the beam angle can be correlated to the photodetector that it hits based on that monitor photodetector's shape, as all of the photodetectors run in parallel to save on the number of conductive traces required.

In some embodiments, a MEMS scanner includes a different plurality of monitor photodetectors. In some embodiments, a MEMS scanner includes only one monitor photodetector. In some embodiments, a MEMS scanner includes 2 photodetectors that are aligned diagonally to enable accurate monitoring of orientation.

MEMS scanner 106 includes scanning element 202, θ-actuator 204-1, φ-actuator 204-2, frame 206, and anchors 208.

In the depicted example, MEMS substrate 112 is a conventional single-crystal silicon wafer suitable for the formation of conventional integrated circuits. In some embodiments, MEMS substrate 112 is a different substrate suitable for use in planar-processing-based MEMS-device fabrication, such as a silicon-on-insulator substrate, a glass substrate, a compound semiconductor substrate, and the like. Materials suitable for use in MEMS substrate 112 include, without limitation, polysilicon, silicon carbide, silicon-germanium, III-V semiconductors, II-VI semiconductors, glasses, dielectrics, ceramics, composite materials, and the like.

Cavity 114 is defined under MEMS scanner 106 by removal of substrate material—typically, after the MEMS scanner has been fully fabricated. Cavity 114 is formed such that it is deep enough to enable a desired angle of rotation about each of the θ-axis and φ-axis. In the depicted embodiment, cavity 114 extends completely through MEMS substrate 112; however, in some embodiments, it does not extend completely through its substrate. In some embodiments, MEMS substrate 112 does not include cavity 114.

The inclusion of cavity 114 enables location of light source 102 below the plane of MEMS scanner 106 (i.e., plane P1), which provides several advantages. First, it enables the scanning element and light source to be positioned in close proximity, thereby enabling a reduced angle-of-incidence on the scanning element, which allows output beam OB1 to exit housing 110 closer to the center of the scan range of MEMS scanner 106. Second, it enables the use of a larger focal length for optical element 104, thereby reducing divergence of collimated beam CB1. Third, it enables a smaller housing to be used, since a portion of the path length of light signal LS1 is within the MEMS scanner thickness.

As discussed below, in some embodiments, light source 102 is located directly beneath scanning element 202.

Scanning element 202 is a mirror suitable for fabrication via planar processing techniques. In the depicted example, scanning element 202 is an aluminum-based mirror that is configured to be movable relative to MEMS substrate 112 and operatively coupled with each of θ-actuator 204-1 and φ-actuator 204-2 (referred to, collectively, as actuators 204). In some embodiments, scanning element 202 comprises a different material suitable for use as a MEMS structural material, such as polysilicon, silicon carbide, silicon-germanium, silicon-dioxide a III-V semiconductor, a II-VI semiconductor, a composite material, and the like. In some embodiments, scanning element 202 has a shape other than circular, such as square, elliptical, irregular, etc. In some embodiments, scanning element 202 is other than a mirror, such as a diffractive optical element (DOE), a Fresnel zone plate, a reflective lens, a refractive lens, a prism, a holographic element, a metasurface, a metalens, and the like.

θ-actuator 204-1 is a torsional thermal actuator operative for rotating scanning element 202 about the θ-axis, which is substantially aligned with the x-axis in the depicted example. θ-actuator 204-1 includes a pair of torsion elements 210-1 and 210-2, each of which is mechanically coupled between scanning element 202 and frame 206 by structural beams. These structural beams and frame 206 are substantially rigid mechanical elements comprising the same structural material as scanning element 202 (i.e., single-crystal silicon, aluminum and silicon dioxide, etc.).

φ-actuator 204-2 is a torsional thermal actuator operative for rotating scanning element 202 about the φ-axis, which is substantially aligned with the y-axis in the depicted example. φ-actuator 204-2 includes torsion elements 210-3 and 210-4, each of which is mechanically coupled between frame 206 and anchors 208 by structural beams. Anchors 208 are conventional mechanical structures that are immovably attached to MEMS substrate 116 outside the confines of cavity 114.

Each of torsion elements 210-1, 210-2, 210-3, and 210-4 includes a plurality of bimorph elements, which are grouped into operative sets. Adjacent operative sets are rigidly interconnected via structural beams such that bending of the operative sets within a torsion element is additive. For clarity, elements comprising structural material (e.g., the material of scanning element 202, frame 206, and anchors 208) are depicted without cross-hatching, while bimorph elements are depicted with cross-hatching.

Scanning element 202, θ-actuator 204-1, φ-actuator 204-2, and frame 208 collectively define a gimbal-mounted structure capable of rotating in two dimensions.

Embodiments in accordance with the present disclosure are afforded significant advantages over the prior art by virtue of the use of electro-thermo-mechanical actuators to control the position of scanning element 202 about its rotation axes. Some of these advantages include:
i. CMOS-compatible operating voltage (3.3V); or
ii. small footprint (present embodiment 700 μm×700 μm); or
iii. large static angular deflection (>+/−45 degrees mechanical in 2 DOF); or
iv. low power (<10 mW); or
v. high speed (≥5-kHz resonance); or
vi. low cost; or
vii. any combination of i, ii, iii, iv, v, and vi.

Preferably, MEMS scanner 106 and monitor photodetectors 108 are fabricated in a conventional CMOS foundry. Examples of actuators suitable for use in scanning element 202, as well as methods suitable for forming them, are described in detail in the parent applications of this application, as well as in U.S. Patent Publication 20150047078, entitled “Scanning Probe Microscope Comprising an Isothermal Actuator,” published Feb. 12, 2015, and U.S. Patent Publication 20070001248, entitled “MEMS Device Having Compact Actuator,” published Jan. 4, 2007, each of which is incorporated herein by reference.

In some embodiments, at least one of actuators 204 is an isothermal actuator to mitigate parasitic effects that arise from thermal coupling between axes of rotation. For the purposes of this Specification, including the appended claims, “isothermal operation” is defined as operation at a constant power dissipation throughout an operating range. A device or system that operates in isothermal fashion dissipates constant power over its operating range, which results in a steady-state heat flow into and out of the device or system. For example, an isothermal actuator is an actuator that operates at a constant power throughout its operating range. In some cases, an isothermal actuator includes a plurality of actuating elements where at least one of the actuating elements operates in non-isothermal fashion; however, the plurality of actuating elements is arranged such that they collectively operate in isothermal fashion.

In some embodiments, therefore, torsion elements 210-1, 210-2, 210-3, and 210-4 are rigidly connected and arranged such that each pair rotates about its respective axis in the same direction when subjected to opposite temperature changes. As a result, their collective power dissipation remains constant during operation. The temperature of the torsion elements is controlled via controlling electrical power dissipation (i.e., ohmic heating) in the torsion elements themselves. In some embodiments, the temperature of the bimorphs in the torsional elements is controlled by controlling power dissipation in ohmic heaters disposed on the torsion elements. In some embodiments, a heat source external to the torsion elements is used to control their temperature, such as heater elements disposed on the surface of MEMS substrate 112.

In some embodiments, at least one of actuators 204 is an isothermal piston actuator operative for rotating a scanning element 202 about an axis while simultaneously giving rise to vertical actuation in response to a temperature change.

It should be noted that, although thermal actuators are preferred, other types of actuators can be used for one or both of actuators 204 without departing from the scope of the present disclosure. Examples of actuators suitable for use in accordance with the present disclosure include, without limitation, electrostatic actuators, magnetic actuators, piezoelectric actuators, pneumatic actuators, hydraulic actuators, magnetostrictive actuators, and the like.

Housing 110 includes substrate 116, body 118, and cover 120, which collectively define chamber 122. Chamber 122 encloses light source 102, optical element 104, MEMS scanner 106, and monitor photodetectors 108. Typically, chamber 122 is substantially sealed to provide a protective environment for the light source and MEMS scanner. In some embodiments, chamber 122 is under vacuum. In some embodiments, chamber 122 is filled with a gas, such as forming gas, nitrogen, argon, and the like.

Preferably, housing 110 is configured to protect light source 102, MEMS scanner 106, and monitor photodetector 108 from electrostatic discharge. It is also desirable that housing 110 mitigate stray reflections light signal LS1, collimated beam CB1, and output beam OB1. In the depicted example, housing 110 is configured to realize both electrostatic protection and mitigation of scattered optical energy.

Substrate 116 is a conventional die-attach substrate suitable for mounting one or more semiconductor die, such as MEMS substrate 112.

Body 118 comprises wall 124, which includes core layer 126.

Wall 124 comprises a material that provides good mechanical strength and is also absorptive for the wavelengths of light signal LS1. In the depicted example, wall 124 comprises bismaleimide-triazine (BT) resin; however, one skilled in the art will recognize that myriad materials can be used in wall 124, such as polymers, epoxies, and the like. In some embodiments, wall 124 is a conventional packaging material whose interior surface is coated with an absorptive material. Conventional packaging materials suitable for use in accordance with the present disclosure include, without limitation, low-temperature co-fired ceramic (LTCC), high-temperature co-fired ceramic (HTCC), other ceramics, printed circuit board (PCB) material, polymers, glasses, composite materials, molding compounds, etc.

Core layer 126 is a solid layer of electrically conductive material that extends through the full height of body 118. In some embodiments, core layer 126 comprises a plurality of conductive vias, rather than a solid layer, where the spacing of the vias is sufficient to provide electrostatic shielding for components contained in chamber 122.

Preferably, height h1 of wall 124 is carefully controlled, which enables precise control over the path length between light source 102 and optical element 106. By controlling this path length, it can be possible to realize a particular desired divergence of output beam OB1.

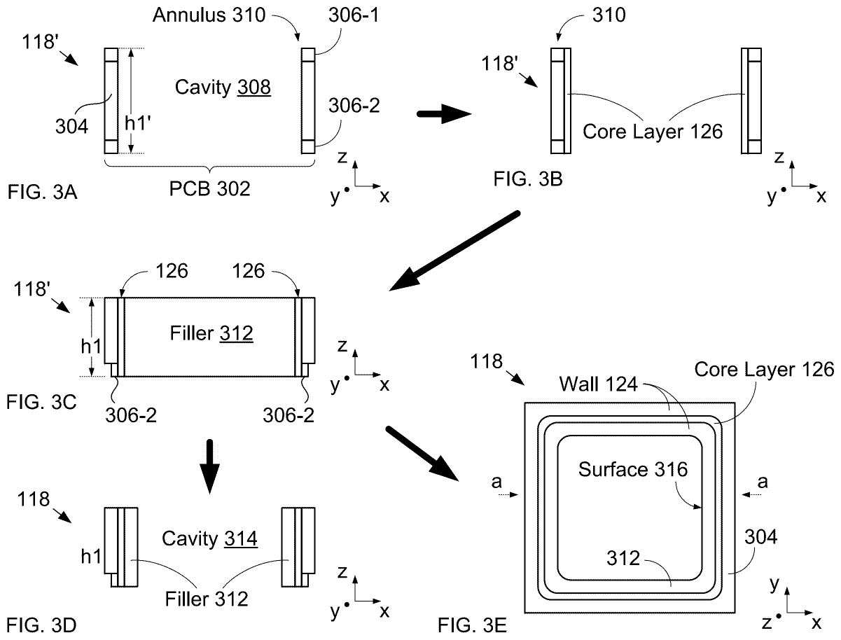

FIGS. 3A-E depict body 118 at different stages of an exemplary fabrication process suitable in accordance with the present disclosure. The sectional views of body 118 shown in FIGS. 3A-D are taken through line a-a of the plan view of body 118 depicted in FIG. 3E. Method 300 begins by forming cavity 308 in printed-circuit board (PCB) 302.

PCB 302 is a conventional two-layer printed-circuit board having central layer 304 between conductive layers 306-1 and 306-2. Typically, central layer 304 comprises an epoxy resin, such as FR4 or bismaleimide-triazine (BT) resin, while conductive layers 306-1 and 306-2 comprise copper; however, a wide range of other materials can be used in PCB 302. Preferably, the initial thickness, h1′, of PCB 304 is greater than the desired height h1 of body 118.

Cavity 308 is formed in PCB 302 by patterning each of conductive layers 306-1 and 306-2 to expose the center areas of each the top and bottom surfaces of central layer 304, followed by removal of the interior portion of central layer 304 in conventional fashion, thereby leaving annulus 310. Nascent body 118′, after formation of cavity 308, is depicted in FIG. 3A.

Once cavity 308 has been formed, core layer 126 is formed on the sidewalls of annulus 310 using conventional plating techniques. In the depicted example, core layer 126 comprises copper; however, other materials can be used for a core layer without departing from the scope of the present disclosure.

FIG. 3B depicts nascent body 118′ after the formation of core layer 126.

Cavity 308 is then filled with filler 312, where filler 312 comprises a material that is substantially absorbing for the wavelengths of light signal LS1. A wide range of materials can be used in filler 312 including, without limitation, epoxy resins (e.g., FR4 or BT resin) and the like.

After cavity 308 has been filled with filler 312, the remaining material of conductive layer 306-2 is optionally patterned as desired. In the depicted example, conductive layer 306-2 is patterned to define a conductive ring for enabling electrical contact between core layer 126 and substrate 112, as discussed below.

The thickness of nascent body 118 is then reduced to establish the desired final height, h1, of wall 124 using a conventional, high-accuracy method, such as precision grinding, lapping, and/or polishing, as depicted in FIG. 3C.

The fabrication of body 118 is then completed with the formation of cavity 314 in filler 312 conventional fashion (via, for example, laser etching, sandblasting, ion milling, reactive ion etching, etc.). The shape of cavity 314 is typically based on the desired shape of chamber 122.

FIGS. 3D-E depict sectional and plan views, respectively, of completed body 118.

When body 118 is completed, wall 124 comprises the residual material of filler 312 and the residual material of central layer 304, which are disposed on either side of core layer 126. It should be noted that, although the depicted example includes a core layer that defines a continuous wall around cavity 314, in some embodiments, core layer 126 comprises a plurality of closely spaced, electrically conductive columns.

In some embodiments, surface 316 of the interior portion of wall 124 is treated (e.g., laser engraving, material deposition, chemical treatment, etc.) to further reduce its reflectivity for wavelengths of light signal LS1 and/or mitigate transmission of light through wall 124.

It should be noted that method 300 is merely one exemplary method for fabricating body 118. One skilled in the art will recognize, after reading this Specification, that myriad alternative methods can be used to form body 118 without departing from the scope of the present disclosure.

Returning now to FIGS. 1 and 2, cover 120 is a conventional glass substrate having inner surface 130 and outer surface 132. In the depicted example, cover 120 includes substantially transparent conductive layer 134 on inner surface 130. In some embodiments, cover 120 is made of a different suitable material, such as a glass, a plastic, a polymer (e.g., PMMA, SU-8, etc.), a composite material, another IR-transparent material, and the like.

In the depicted example, conductive layer 134 is a layer of indium tin oxide (ITO); however, other transparent conductive materials can be used in conductive layer 130. Conductive layer 134 is thin enough to be highly transparent for output beam OB1, while also giving rise to monitor signal MS1 due to Fresnel reflections at the conductive layer. MS1 provides a local optical feedback signal based on the position of scanning element 202, which is detected by monitor photodetectors 108.

In some cases, as output beam OB1 passes through cover 120, Fresnel reflection occurs at each of inner surface 130 and outer surface 132. This can give rise to double reflections that merge into monitor signal MS1, leading to errors in the detected position of scanning-element 202. To mitigate these double reflections, in the depicted example, inner surface 130 includes an anti-reflection (AR) coating 136 that enables output beam OB1 to pass through it with little or no reflection, while outer surface 132 does not include an AR coating to enable Fresnel reflections at this surface to give rise to monitor signal MS1. In some embodiments, outer surface 132 includes AR coating 136, while inner surface 130 does not. In some embodiments, each of inner surface 130 and outer surface 132 includes an AR coating such that monitor signal MS1 arises from a Fresnel reflection from an optical element that is located external to housing 110.

Alternatively, in some embodiments, the thickness of cover 120 is increased to more fully separate the reflected signals arising from Fresnel reflections at both inner surface 130 and outer surface 132. Such an arrangement of surfaces can be exploited to increase the number of points available for determining the position of scanning element 202.

Cover 120 and body 118 are mechanically joined via a first conventional seal ring 128, which also establishes electrical connectivity between core layer 126 and conductive layer 134. In similar fashion, substrate 116 and core layer 126 are mechanically joined via a second conventional seal ring 128, which also establishes electrical connectivity between the substrate and the core layer. As a result, substrate 116, core layer 126, and conductive layer 134 collectively form an electrostatic shield for chamber 122.

In some embodiments, a single substrate is used for MEMS substrate 112 and housing substrate 116 (i.e., MEMS substrate 112 and substrate 116 are the same substrate). As will be apparent to one skilled in the art, after reading this Specification, in such embodiments, cavity 114 does not extend through the entire thickness of this substrate.

In some embodiments, optical element 104 is integrated into at least one of inner surface 130 and outer surface 132 of cover 120.

As noted above, preferably, a beam scanner in accordance with the present disclosure mitigates the propagation of stray light, which can couple into other parts of larger systems in which the beam scanners are used. In the depicted example, MEMS scanner 106 includes optional mitigation regions 212, which comprise absorbing material (e.g., polyimide, etc.) for wavelengths included in light signal LS1.

In some embodiments, rather than absorbing stray light at mitigation regions 212, the mitigation regions are configured to proactively redirect stray light toward specific regions of housing 110 (e.g., absorbing wall 124) where it is safely removed from the system.

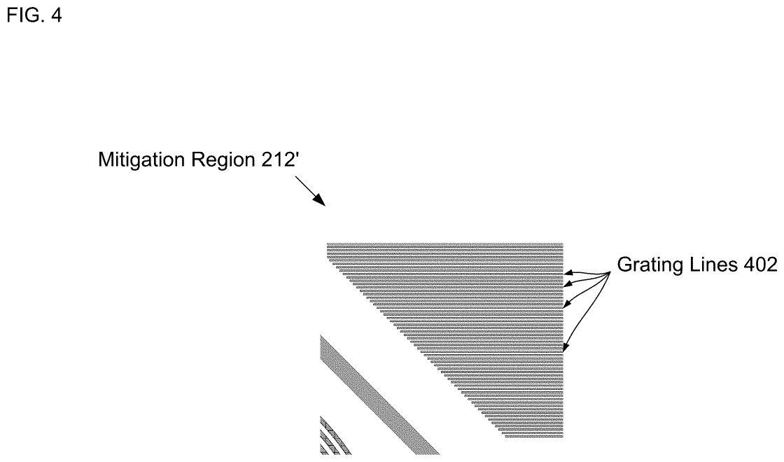

FIG. 4 depicts a schematic drawing of an alternative mitigation region in accordance with the present disclosure. In the depicted example, mitigation region 212′ includes a series of grating elements 402, which collectively define a diffraction grating operative for redirecting light scattered within housing 110 toward wall 124. Additional examples of alternative mitigation regions are described in more detail in parent applications U.S. Ser. Nos. 17/681,503 and 16/232,410.

It should be noted that the grating structure is preferably located underneath oxide to prevent delamination. In some cases, this also enables the oxide to reduce surface reflection.

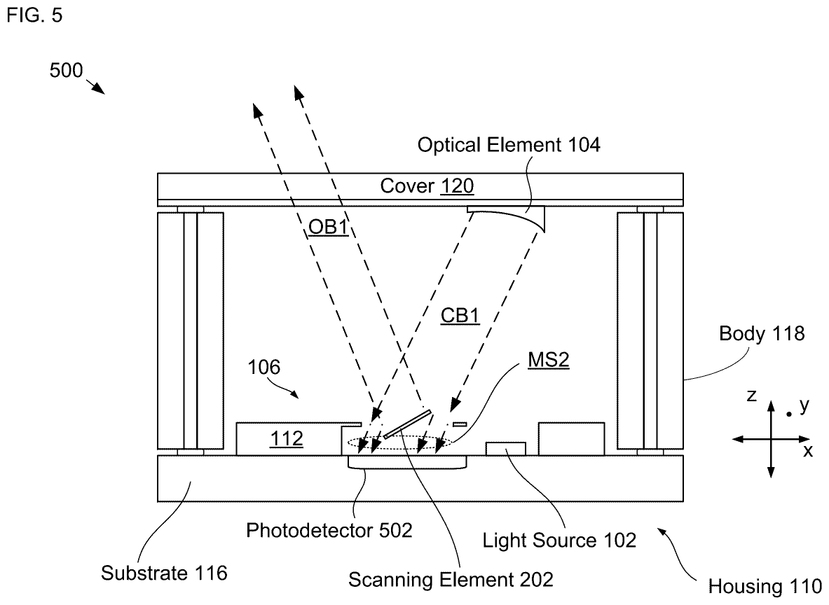

FIG. 5 depicts a schematic drawing of a cross-sectional view of an alternative embodiment of a beam scanner suitable for use in an object-tracking system in accordance with the present disclosure. Beam scanner 500 is analogous to beam scanner 100; however, in beam scanner 500, a monitor photodetector is located beneath scanning element 202.

Monitor photodetector 502 is configured such that it accepts enough light to register a signal. The photodetector is typically much smaller than the beam diameter such that a falling and rising edge can be detected as the beam passes the photodetector. The photodetectors must be spaced such that there is at least a beam diameter between each sensor to allow defined falling and rising edges as all photodetectors are wired together in a parallel configuration.

As depicted in FIG. 5, scanning element 202 is oriented at an angle relative to its quiescent position, which reduces the cross-sectional area of the scanning element between optical element 104 and monitor photodetector 502. As will be appreciated by one skilled in the art, after reading this Specification, as scanning element 502 rotates about each of the θ-axis and φ-axis, the area of monitor photodetector 502 exposed to collimated beam CB1 depends on the instantaneous position of the scanning element. As a result, the output signal of monitor photodetector 502 can be used as a local feedback signal that is indicative of scanning-element position.

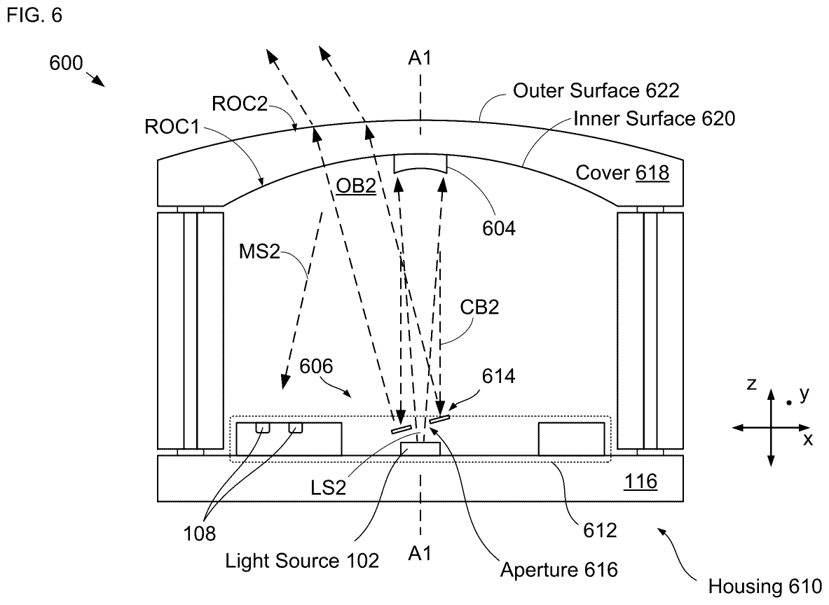

FIG. 6 depicts a schematic drawing of a cross-sectional view of another alternative embodiment of beam scanner suitable for use in an object-tracking system in accordance with the present disclosure. Beam scanner 600 includes light source 102, optical element 604, MEMS scanner 606, and monitor photodetectors 108, all of which are contained within housing 610.

Optical element 604 is analogous to optical element 104 and is disposed at the center of inner surface 620 of cover 618. In the depicted example, optical element 604 is a spherical reflective lens configured to collimate light signal LS2 and reflect it as collimated beam CB2 toward scanning element 614 of MEMS scanner 606. As noted above and with respect to optical element 104, myriad optical elements can be used for optical element 604 without departing from the scope of this disclosure, such as, without limitation, reflective lenses, diffractive elements, holographic elements, metalenses, metasurfaces, and the like. Furthermore, in some embodiments, a portion of inner surface 620 or outer surface 622 (with an optional reflective coating) functions as a reflective element itself, thereby obviating the need for an additional optical element in the system.

MEMS scanner 606 is analogous to MEMS scanner 106. MEMS scanner 606 comprises scanning element 614, which is substantially scanning element 202 with the addition of aperture 616 located at its center. Aperture 616 enables light signal LS2 to pass through scanning element 614 enroute to optical element 604.

Preferably, scanning element 614, aperture 616, light source 102, and optical element 604 are aligned along axis A1.

Housing 610 is analogous to housing 110; however, housing 610 includes cover 618, which has a substantially uniform dome shape. Inner surface 620 of cover 618 has radius of curvature ROC1, which enables output beam OB2 to hit inner surface 618 at normal incidence over the entire scan range of scanning element 614. In some embodiments, cover 618 is configured such that output beam OB2 hits inner surface 620 at an angle of incidence other than normal.

In the depicted example, cover 618 includes outer surface 622 such that this surface has radius of curvature ROC2, which is larger than ROC1. Such a configuration of surfaces substantially defines a refractive lens that increases the deflection angle for output beam OB2 as it passes through cover 618, thereby increasing the scan range of beam scanner 600. In some embodiments, the inner and outer surfaces of cover 618 have the same radius of curvature. In some embodiments, inner surface 620 has a greater radius of curvature than outer surface 622.

In some embodiments, the curvature of cover 618 is sufficient to obviate the need for sidewalls (i.e., body 118) between the cover and substrate 116. In such embodiments, cover 618 is directly joined to substrate 116 via a seal ring (e.g., seal ring 128).

In some embodiments, scanning element 614 has a curved concave surface that, in conjunction with optical element 604, collectively collimates light signal LS2 to form collimated beam CB2. In some embodiments, scanning element 614 includes a metasurface that at least partially collimates light to form collimated beam CB2.

In some embodiments, optical element 604 is a metasurface that diverges light signal LS2 from the light source 102 such that scanning element 614 receives a “shaped” light signal CB2′ that has a substantially dark central region (i.e., it gives rise to a “donut-like” spot on scanning element 614). Such a metasurface reduces or eliminates the amount of the optical energy of light signal CB2′ that passes through aperture 616 to hit light source 102. In some such embodiments, scanning element 614 is configured such that it has a desired curvature that enables the scanning element to at least partially collimate collimated beam CB2 (or shaped light signal CB2′) while simultaneously steering it as output beam OB2. It should be noted that a “donut-like” spot is merely one example of an illumination pattern that can be generated by optical element 604 on scanning element 614 and an optical element can form any desired illumination pattern on a scanning element without departing from the scope of the present disclosure.

In some embodiments, the scanning element 614 also has a metasurface which can help to collimate light signal CB2′ after it has diverged from optical element 604. This divergence can facilitate subsequent additional collimation of light signal CB2′ as it travels along its optical path.

It is to be understood that the disclosure teaches just some examples of embodiments in accordance with the present invention and that many variations of the invention can easily be devised by those skilled in the art after reading this disclosure and that the scope of the present invention is to be determined by the following claims.

What is claimed is:

1. A beam scanner comprising:
a light source configured to provide a light signal;
an optical element configured to receive the light signal and provide a first portion of the light signal as a collimated beam;
a MEMS scanner that is operative for steering the first portion in two dimensions, the MEMS scanner including a scanning element, a first actuator for rotating the scanning element about a first axis, and a second actuator for rotating the scanning element about a second axis;
a first photodetector that is configured to provide a feedback signal based on a second portion of the light signal, wherein the second portion is based on an orientation of the scanning element about at least one of the first axis and second axis; and
a housing that includes a first substrate, a body, and a cover that comprises a first material that is substantially transparent for the light signal, wherein the first substrate, body, and cover collectively define a chamber that is sealed to maintain a first environment, and wherein the chamber contains the light source, the MEMS scanner, and the first photodetector;
wherein the MEMS scanner directs the first portion through the cover as an output signal.

2. The beam scanner of claim 1 wherein at least one of the first actuator and second actuator is a thermal actuator.

3. The beam scanner of claim 1 wherein the first photodetector and the MEMS scanner are monolithically integrated on a second substrate.

4. The beam scanner of claim 1 further comprising a second photodetector and a third photodetector, wherein the first, second, and third photodetectors and the MEMS scanner are monolithically integrated on a second substrate.

5. The beam scanner of claim 1 wherein the first photodetector and the MEMS scanner are monolithically integrated on the first substrate, and wherein the first substrate, the cover, and the body are joined to collectively define the housing.

6. The beam scanner of claim 1 wherein the cover includes an inner surface and an outer surface, and wherein only one of the first surface and second surface includes an anti-reflection coating.

7. The beam scanner of claim 1 wherein the housing includes a sidewall that is configured to absorb a reflection of the light signal.

8. The beam scanner of claim 1 wherein the housing includes a sidewall that is electrically conductive, and wherein the cover includes a first surface that is electrically conductive, and further wherein the sidewall, the first surface, and the first substrate collectively define an electrically conductive shield that substantially surrounds the chamber.

9. The beam scanner of claim 1 wherein the scanning element is held above a first cavity, and wherein the light source is located in the first cavity.

10. The beam scanner of claim 9 wherein the scanning element includes the optical element, the optical element being a metalens, and wherein the cover has a dome shape comprising an inner surface and an outer surface, and further wherein the optical element, the aperture, and the VCSEL are aligned along a third axis.

11. The beam scanner of claim 9 wherein the scanning element includes an aperture that enables the light signal to propagate through the scanning element, and wherein the cover has a dome shape comprising an inner surface and an outer surface, the optical element being disposed on the inner surface, and wherein the light source includes a vertical-cavity surface-emitting laser (VCSEL) having an annular shape, and further wherein the optical element, the aperture, and the VCSEL are aligned along a third axis.

12. The beam scanner of claim 11 wherein the inner surface has a first radius of curvature and the second surface has a second radius of curvature that is not equal to the first radius of curvature.

13. The beam scanner of claim 1 wherein the MEMS scanner includes a mitigation region that is configured to mitigate reflection of the light signal.

14. The beam scanner of claim 1 wherein the MEMS scanner includes a mitigation region comprising a diffraction grating for diffracting a reflection of the light signal.

15. A method including:
providing a housing that includes a first substrate, a body, and a cover that comprises a first material that is substantially transparent for a light signal, wherein the first substrate, body, and cover collectively define a chamber that is sealed to maintain a first environment, and wherein the chamber contains a light source, an optical element, a MEMS scanner, and a first photodetector;
enabling the light source to provide the light signal;
collimating the light signal at the optical element as a collimated beam and directing the collimated beam to a MEMS scanner comprising a scanning element for steering the collimated beam in two dimensions, wherein the MEMS scanner includes the scanning element, a first actuator for rotating the scanning element about a first axis, and a second actuator for rotating the scanning element about a second axis;
providing a feedback signal based on a first portion of the light signal, wherein the feedback signal is provided by the first photodetector, and wherein the first portion is based on an orientation of the scanning element about at least one of the first axis and second axis; and
directing a second portion of the collimated beam through the cover as an output signal via the MEMS scanner.

16. The method of claim 15 further comprising providing the first photodetector and the MEMS scanner such that they are monolithically integrated.

17. The method of claim 15 further comprising providing the cover such that it has an inner surface and an outer surface, and wherein only one of the inner surface and outer surface includes an anti-reflection coating.

18. The method of claim 15 further comprising providing the scanning element such that it is held above a first cavity that contains the light source.

19. The method of claim 18 further comprising providing the MEMS scanner such that the scanning element includes an aperture that enables the light signal to propagate through the scanning element, and wherein the cover has a dome shape comprising an inner surface and an outer surface, the first optical element being disposed on the inner surface, and wherein the light source includes a vertical-cavity surface-emitting laser (VCSEL) having an annular shape, and further wherein the first optical element, the aperture, and the VCSEL are aligned along a third axis.

20. The method of claim 15 further comprising providing the housing such that the first substrate, the body, and the cover collectively define an electrically conductive shield that substantially surrounds the chamber, wherein the body is configured to absorb optical energy of a reflection of the collimated beam.
